(19) United States
(12) Patent Application Publication
(10) Pub. No.: US 2009/0310325 A1
(43) Pub. Date: Dec. 17, 2009

(54) PORTABLE ELECTRONIC DEVICE AND METHOD FOR SEARCHING BUS ROUTE INFORMATION THEREOF

(75) Inventors: Shih-Fang Wong, Tu-Cheng (TW); Yi-Feng Weng, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/248,000

(22) Filed: Oct. 8, 2008

(30) Foreign Application Priority Data
Dec. 14, 2007 (CN) 200710203067.5

(51) Int. Cl. H05K 7/02

(52) U.S. Cl. 361/807

(57) ABSTRACT

A portable electronic device includes a positioning module, a memory, a searching module, and a display module. The positioning module is used for receiving positioning signals and determining a current position of the portable electronic device according to the positioning signals. The memory is used for storing electronic map information, bus route information, and mapping relations between the electronic map information and the bus route information. The searching module is used for searching the nearest bus station corresponding to the current position of the portable electronic device and bus routes that goes to the nearest bus station in the memory. The display module is used for displaying the nearest bus station and the bus routes that goes to the nearest bus station on the electronic map.

### BACKGROUND

1. Technical Field

Embodiments of the present disclosure generally relate to portable electronic devices and methods for searching bus route information thereof.

2. Description of Related Art

A portable electronic device, such as a mobile phone or a personal digital assistant (PDA) may be able to provide navigation information to users.

When a commuter chooses to get to his destination by bus, the commuter not familiar with the area may not know bus station locations and bus routes. Especially, when the commuter need to transfer more than once, the commuter may spend a lot of time looking for the appropriate bus station and buses to get to his destination.

Therefore, improved portable electronic devices and methods for searching bus route information are needed to address the aforementioned problems associated with a commuter.

### SUMMARY

Accordingly, a portable electronic device is provided. The portable electronic device includes a positioning module, a memory, a searching module, and a display module. The positioning module is used for receiving positioning signals and determining a current position of the portable electronic device according to the positioning signals. The memory is used for storing electronic map information, bus route information, and mapping relations between the electronic map information and the bus route information. The searching module is used for searching the memory for the nearest bus station, corresponding to the current position of the portable electronic device, and bus routes to the nearest bus station. The display module is used for displaying the nearest bus station and the bus routes on the electronic map. A method for searching bus route information is also disclosed.

Other advantages and novel features of the present disclosure will become apparent from the following detailed description of the embodiment when taken in conjunction with the accompanying drawings.

### BRIEF DESCRIPTION OF THE DRAWINGS

FIG. 1 is a schematic block diagram of one embodiment of a portable electronic device; and

FIG. 2 is a flow chart illustrating one embodiment of a method for searching bus route information of the present disclosure.

### DETAILED DESCRIPTION OF THE EXEMPLARY EMBODIMENTS

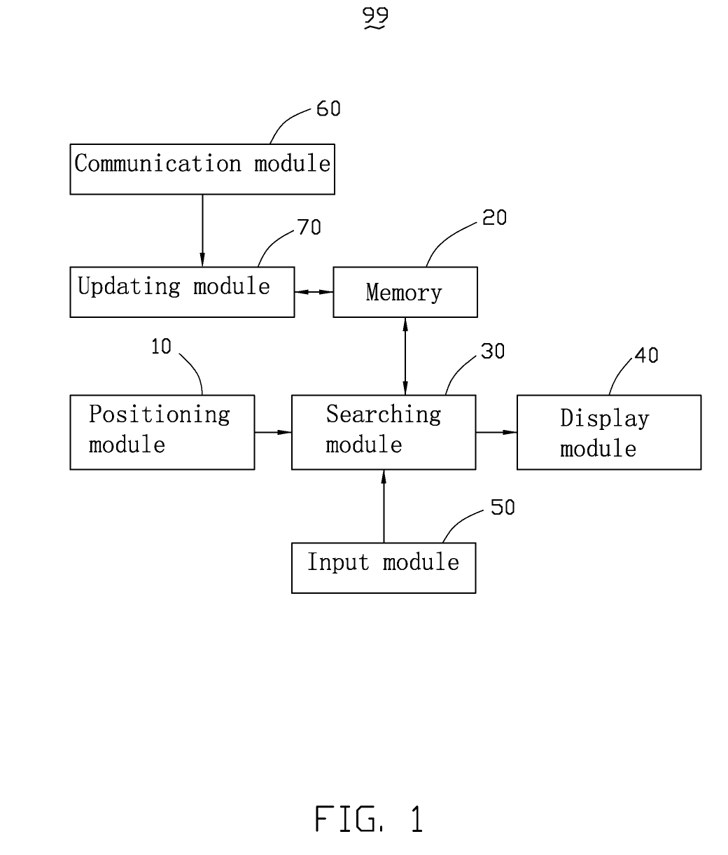

Referring to FIG. 1, a portable electronic device 99 in accordance with one embodiment is illustrated. The portable electronic device 99 includes a positioning module 10, a memory 20, a searching module 30, a display module 40, an input module 50, a communication module 60, and an updating module 70. The portable electronic device 99 may be a mobile phone or a personal digital assistant (PDA).

The positioning module 10 is used for receiving positioning signals and determining a current position of the portable electronic device 99 according to the positioning signals. It may be understood that the positioning signals may be provided by positioning satellites.

The memory 20 is used for storing electronic map information, bus route information, and mapping relations between the electronic map information and the bus route information. The bus route information includes, but not limited to, bus station names, bus station locations, and bus routes to the bus stations.

The searching module 30 is used for searching the memory 20 for the nearest bus station corresponding to the current position of the portable electronic device 99 and bus routes that leads to the nearest bus station.

The display module 40 is used for displaying the nearest bus station and the bus routes that lead to the nearest bus station on the electronic map. Therefore, the nearest bus station and the bus routes that go to the nearest bus station can be known by one using the portable electronic device 99. One using the portable electronic device 99 needs not spend a lot of time looking for an appropriate bus station and buses to lead to a destination.

In one embodiment, electronic signals may be inputted to the portable electronic device 99 by the input module 50 to designate a final destination. The input module 50 sends the electronic signals to the searching module 30. The searching module 30 searches bus routes leading to the nearest bus station and also searches for the bus routes leading to the final destination. The display module 40 displays the bus routes to the nearest bus station and also the bus route to the final destination. One using the portable electronic device 99 can further conveniently know the appropriate bus stations and board the buses that would lead to the final destination.

In one embodiment, the information stored in the memory 20 may be necessary to be updated so that bus route information displayed on the electronic map is substantially correct. The communication module 60 is used for receiving electronic map information or bus route information from other devices such as bus route information servers or electronic map information servers via networks. The updating module 70 is used for updating the electronic map information or bus route information stored in the memory 20 according to the electronic map information or bus route information received by the communication module 60.

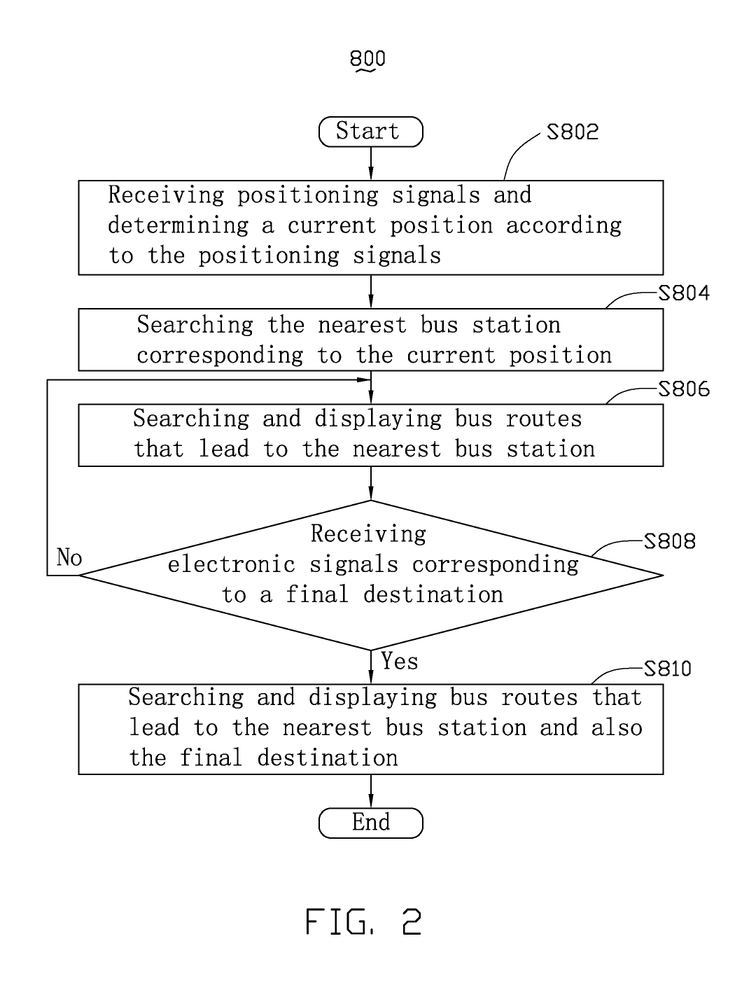

Referring to FIG. 2, a procedure of a method 800 for searching bus route information accordance with an exemplary embodiment is illustrated. The method 800 may be implemented using the portable electronic device 99 (FIG. 1). The various actions in the method 800 may be performed in the order presented, or may be performed in a different order. Furthermore, in some embodiments, some actions listed in FIG. 2 may be omitted from the method 800. The method 800 includes the following steps:

Beginning in step S802, receiving positioning signals and determining a current position of the portable electronic device 99 according to the positioning signals.

In step S804, searching the nearest bus station of the portable electronic device 99 corresponding to the current position.

In step S806, searching and displaying bus routes leading to the nearest bus station for the current user of the portable electronic device 99. The user need not spend a lot of time looking for an appropriate bus station and buses to lead to a destination.

In step S808, judging whether electronic signals corresponding to a final destination is received, if the electronic signal corresponding to the final destination is received, the procedure goes to step S810. If the electronic signal corresponding to the final destination is not received, the procedure returns to step S806.

In step S810, searching and displaying bus routes that lead to the nearest bus station and also the final destination. The users of the portable electronic device 99 can further conveniently know the appropriate bus station and catch buses that go to the final destination.

It is to be understood, however, even though numerous information and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A portable electronic device comprising:
a positioning module for receiving positioning signals and determining a current position of the portable electronic device according to the positioning signals;
a memory for storing electronic map information, bus route information, and mapping relations between the electronic map information and the bus route information;
a searching module for searching the memory for the nearest bus station corresponding to the current position of the portable electronic device and bus routes that goes to the nearest bus station; and
a display module for displaying the nearest bus station and the bus routes that goes to the nearest bus station on the electronic map.

2. The portable electronic device according to claim 1, further comprising:
an input module for inputting electronic signals corresponding to a final destination for users of the portable electronic device to the searching module, and the searching module searches the memory to determine bus routes that goes to the nearest bus station and also to the final destination.

3. The portable electronic device according to claim 1, further comprising:
a communication module for receiving electronic map information or bus route information from other devices;
an updating module for updating the electronic map information or bus route information stored in the memory according to the electronic map information or bus route information received by the communication module.

4. A method for searching bus route information comprising:
receiving positioning signals and determining a current position of a portable electronic device according to the positioning signals;
searching for the nearest bus station corresponding to the current position of the portable electronic device;
searching and displaying bus routes that lead to the nearest bus station for a current user of the portable electronic device.

5. The method according to claim 4, further comprising:
judging whether an electronic signal corresponding to a final destination is received; and
searching and displaying bus routes that leads to the nearest bus station and to the final destination upon the condition that the electronic signal corresponding to the final destination is received.

6. The method according to claim 5, further comprising:
returning to the step that searching and displaying bus routes that leads to the nearest bus station for one user of the portable electronic device upon the condition that the electronic signal corresponding to the final destination is not received.

7. A method for searching bus route information comprising:
receiving positioning signals and determining a current position of a portable electronic device according to the positioning signals;
searching the nearest bus station of the portable electronic device corresponding to the current position;
judging whether an electronic signal corresponding to a final destination is received; and
searching and displaying bus routes that leads to the nearest bus station and also to the final destination upon the condition that the electronic signal corresponding to the final destination is received.

8. The method according to claim 7, further comprising:
searching and displaying bus routes that leads to the nearest bus station for a current user of the portable electronic device upon the condition that the electronic signal corresponding to the final destination is not received.
